(19) United States
(12) Patent Application Publication
(10) Pub. No.: US 2026/0250846 A1
(43) Pub. Date: Aug. 27, 2026

(54) THIN FILM DEPOSITION DEVICE

(71) Applicant: Samsung Electronics Co., Ltd., Suwon-si (KR)

(72) Inventors: Seungchul Ahn, Suwon-si (KR); Jaehyung Lee, Suwon-si (KR); Hyun Ho Choi, Suwon-si (KR); Jeonghun Park, Suwon-si (KR); Heesun Song, Suwon-si (KR)

(73) Assignee: Samsung Electronics Co., Ltd., Suwon-si (KR)

(21) Appl. No.: 19/331,994

(22) Filed: Sep. 17, 2025

(30) Foreign Application Priority Data
Feb. 26, 2025 (KR) 10-2025-0025379

(51) Int. Cl. C23C 16/455; C23C 16/52

(52) U.S. Cl. CPC C23C 16/45578; C23C 16/52

(57) ABSTRACT

A thin film deposition device according to embodiments includes a tube, a boat disposed within the tube and configured to load a plurality of wafers in parallel at spaced intervals, and a nozzle disposed within the tube along one direction and including a plurality of holes configured to supply a gas toward the wafers, wherein at least one of the plurality of holes has a diameter different from diameters of the others.

### CROSS-REFERENCE TO RELATED APPLICATIONS

This present application claims priority to and the benefit under 35 U.S.C. § 119(a)-(d) of Korean Patent Application No. 10-2025-0025379 filed on Feb. 26, 2025, in the Korean Intellectual Property Office, the entire disclosure of which is incorporated herein by reference.

### FIELD

The present disclosure relates to a thin film deposition device.

### BACKGROUND

CVD (Chemical Vapor Deposition) equipment is a very important equipment in the semiconductor manufacturing process, and is mainly used to deposit a thin film on the surface of a semiconductor wafer.

The CVD process is a process that forms a solid film on a wafer by chemically reacting gas at high temperatures.

Batch CVD equipment is equipment that can form thin films on multiple wafers at once. Since multiple wafers must be processed simultaneously, precise control of temperature and pressure is very important in batch CVD processes. This allows for obtaining a uniform thin film and minimizing problems of impurity inclusion and thickness unevenness.

In addition, since the mixing ratio, flow rate, and supply method of the gas used in the batch CVD process have a significant impact on the process results, gas flow management is important.

That is, when depositing a thin film on multiple wafers placed inside a tube using batch-type CVD equipment, it is important to uniformly supply a reaction gas to multiple wafers placed inside the tube to reduce not only the thickness deviation within a single wafer but also the thickness deviation between multiple wafers.

### SUMMARY

Aspects of the present disclosure attempts to provide a thin film deposition device that reduces the thickness deviation of a thin film occurring within each wafer by controlling the flow rate of a gas supplied onto a wafer placed within a tube by varying the shape of a hole provided in a nozzle.

Aspects of the present disclosure attempts to provide a thin film deposition device that reduces the thickness deviation of a thin film between a plurality of wafers by supplying gas so that the gas distribution inside the tube is uniform by making the sizes of holes provided in the nozzle different.

Aspects of the present disclosure attempts to provide a thin film deposition device that reduces temperature deviation within a tube during a process of uniformly supplying gas, thereby minimizing dispersion of time Propagation Delay (tPD).

Embodiments of the present disclosure provides a thin film deposition device including a tube, a boat disposed within the tube and configured to load a plurality of wafers in parallel at spaced intervals, a nozzle disposed within the tube along one direction and including a plurality of holes configured to supply a gas toward the wafers, wherein at least one of the plurality of holes has a diameter different from a diameter of at least one of the other holes.

Embodiments of the present disclosure provides a thin film deposition device including a tube, a boat disposed within the tube and configured to load a plurality of wafers in parallel, a nozzle disposed within the tube and including a plurality of holes configured to supply a gas toward the wafers, and a pressure controller configured to adjust the pressure inside the tube to be low pressure, wherein at least one of the plurality of holes has a different diameter than a diameter of at least another of the plurality of holes.

Embodiments of the present disclosure provides a thin film deposition device including a tube, a boat disposed within the tube and configured to load a plurality of wafers in parallel, a nozzle fixed at one end to a lower side of the tube and disposed within the tube such that the other end is proximate to an upper side of the tube, the nozzle including a plurality of holes configured to supply a gas toward the wafers, and pressure controller configured to adjust the pressure inside the tube to be low pressure, wherein some of the plurality of holes have diameters that increase toward the other end of the nozzle.

According to aspects of the present disclosure, a thin film deposition device can be provided that reduces a thin film thickness deviation occurring within each wafer by controlling a flow rate of a gas supplied onto each wafer placed within a tube to improve the reaction efficiency of a gas reacting on each wafer.

According to aspects of the present disclosure, a thin film deposition device can be provided that reduces a thin film thickness deviation between a plurality of wafers by supplying gas so that the gas distribution inside the tube is uniform.

According to aspects of the present disclosure, a thin film deposition device can be provided that reduces a temperature deviation within a tube during a process of uniformly supplying gas, thereby minimizing dispersion of time Propagation Delay (tPD).

### BRIEF DESCRIPTION OF THE DRAWINGS

FIG. 1 is a drawing illustrating a thin film deposition device according to embodiments.

FIGS. 2A and 2B are enlarged views of area S of FIG. 1.

FIGS. 3 to 5 are drawings to explain problems that occur in the case of a horizontal nozzle.

FIG. 6 is a drawing illustrating a nozzle of a thin film deposition device according to embodiments.

FIG. 7 is a drawing illustrating a nozzle of a thin film deposition device according to embodiments.

FIG. 8 is a drawing to explain the difference in deposition thickness on the wafer.

FIG. 9 is a drawing illustrating a thin film deposition device according to embodiments.

FIGS. 10A, 10B, and 10C are drawings illustrating changes in the flow rate of gas injected inside a tube.

FIGS. 11A, 11B, 11C, 12A, 12B, 12C, 13A, 13B and 13C are drawings illustrating the injection speed of gas injected from the nozzle of FIGS. 10A, 10B, and 10C.

FIGS. 14A, 14B, and 14C are drawings illustrating the concentration distribution of gas deposited on a wafer.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are irrelevant to the description in the drawings are omitted, and like numerals refer to like or similar constituent elements throughout the specification.

Further, since sizes and thicknesses of constituent members shown in the accompanying drawings are arbitrarily given for better understanding and ease of description. The present disclosure is not necessarily limited to what is illustrated. In the drawings, the size and thickness of layers, films, panels, regions, etc., are exaggerated for clarity. In the drawings, for better understanding and ease of description, the thicknesses of some layers and areas are exaggerated.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, plate, etc. is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, sequence numbers such as 1st, 2nd, etc. are used to distinguish a certain component from other components that are the same or similar thereto, and are not necessarily intended to refer to a specific component. Accordingly, a component referred to as a first component in a specific part of this specification may be referred to as a second component in other parts of this specification.

In addition, throughout the specification, singular references to certain elements include references to a plurality of these elements, unless specifically stated to the contrary. For example, “insulating layer” may be used to indicate not only one wiring layer but also a plurality of insulating layers, such as two, three, or more. Similarly, throughout the specification, components described in the plural may be implemented as singular components.

Additionally, throughout the specification, references to a first side and a second side are intended to distinguish different sides from each other, and are not necessarily intended to limit it to a specific side. Accordingly, a side referred to as a first side in a specific part of this specification may also be referred to as a second side in other parts of this specification.

Furthermore, throughout the specification, references to directions such as upper surface, upper side, upper portion, lower surface, lower side, lower portion, etc. are described to aid description and understanding based on the drawings.

Hereinafter, a thin film deposition device 10 according to embodiments of the present disclosure will be described in detail with reference to the drawings.

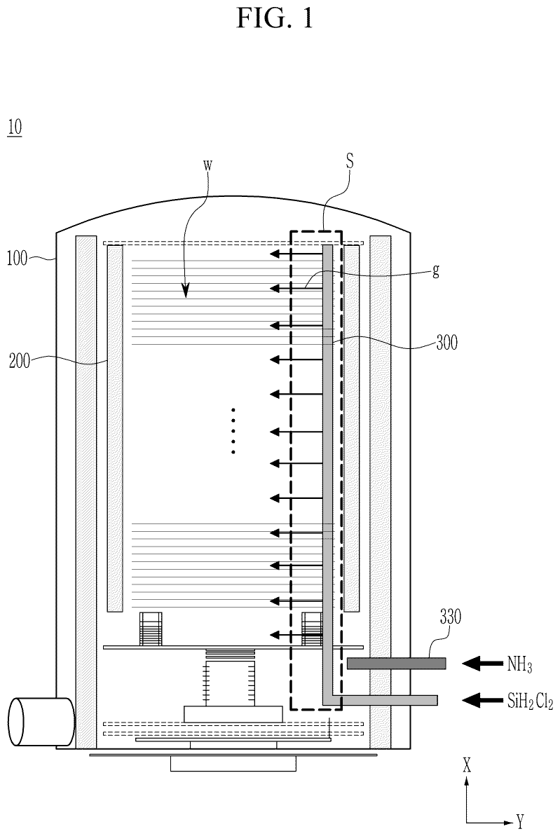

FIG. 1 is a drawing illustrating a thin film deposition device according to embodiments.

As illustrated in FIG. 1, a thin film deposition device 10 according to the present disclosure may include a tube 100, a boat 200, and a nozzle 300.

First, a plurality of wafers (w) can be arranged along one direction (X) inside the tube 100.

The tube 100 is a chamber where a CVD process takes place and may generally have a long tube shape. A chemical reaction material (gas (g)) is heated inside the tube 100 and can be deposited on the wafer (w) in a gaseous state (gas (g)).

The boat 200 is placed inside the tube 100 and can serve to load a plurality of wafers (w) spaced parallel to each other. The boat 200 may have a structure capable of accommodating plurality of wafers (w).

The boat 200 can generally be made of metal or ceramic material. The boat 200 may have a material that minimizes deformation due to thermal expansion or chemical reaction.

A wafer (w) loaded on a boat 200 can be introduced into a tube 100 through the boat 200. A boat 200 in which plurality of wafers (w) are arranged along one direction (X) may have a structure that is introduced into the inside of a tube 100. Typically, the boat 200 can be introduced through the lower portion of the tube 100.

The nozzle 300 can be placed within the tube 100 along the longitudinal direction (directional (X)) of the tube 100. Specifically, one side of the nozzle 300 may be fixed to the lower side of the tube 100, and the other side of the nozzle 300 may be placed within the tube 100 close to the upper side of the tube 100.

One side of the nozzle 300 may have a structure that is introduced into the tube 100 from the outside, as shown in FIG. 1. The nozzle 300 may have an ‘L’ shape as shown in FIG. 1 and may be made of quartz material.

The process of depositing a thin film on the surface of a wafer (w) is a process of supplying gas (g) into a tube 100 through a nozzle 300, and then controlling the temperature inside the tube 100 to chemically react the gas (g) at a high temperature to form a solid film on the wafer (w).

A nozzle 300 according to the present disclosure may include a nozzle 300 that supplies SiH₂Cl₂.

In addition, the thin film deposition device 10 according to the present disclosure may further include an NH₃ nozzle 330 that supplies NH₃ into the tube 100. The NH₃ nozzle 330 may have a straight-line structure, as shown in FIG. 1.

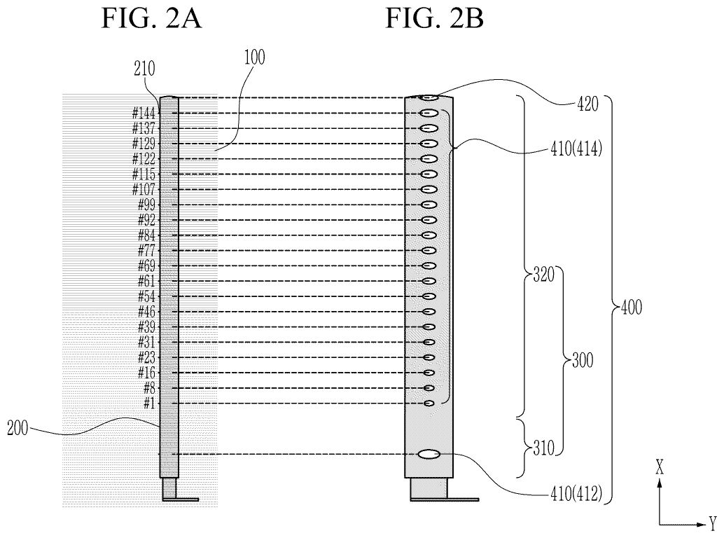

FIG. 2 is an enlarged view of area S of FIG. 1.

FIG. 2A is an enlarged drawing of the interior of a boat 200 included in area S of FIG. 1. FIG. 2B is a drawing showing a nozzle 300 so that the position of the hole 400 of the nozzle 300 included in the S region of FIG. 1 is visible.

The boat 200 shown in FIG. 2A is provided with a plurality of slots 210. A plurality of wafers (w) can be loaded so as to be placed across each slot 210 of a protruding shape (see FIG. 1 and FIG. 2A).

In the boat 200 shown in FIG. 2A, each slot 210 is numbered. The numbering shown in FIG. 2A indicates the order of the slots 210.

A boat 200 may be provided with a plurality of slots 210.

Only 20 slots 210 are shown in FIG. 2A. However, in reality, the number of slots 210 provided in the boat 200 of FIG. 2A may be 144 in total. That is, the numbering is made up of numbers listed in order from 1 to 144, and in FIG. 2A, some slots 210 are omitted and only 20 slots 210 are shown.

Although 144 slots 210 are illustrated in FIG. 2A, the number of slots 210 is not limited thereto.

Referring to FIG. 1 and FIG. 2B, the nozzle 300 according to the present disclosure may include a plurality of holes 400 that supply gas (g) toward the wafer (w).

In FIG. 1, a plurality of holes 400 are not illustrated, and only the gas (g) supplied through the holes 400 is illustrated. The location and shape of the plurality of holes 400 are shown in FIG. 2B.

Looking at the nozzle 300 illustrated in FIG. 2B, it can be confirmed that some of the plurality of holes 400 included in the nozzle 300 correspond to the positions of the slots 210 illustrated in FIG. 2A. Except for the hole 420 located at the top and the hole 412 located at the bottom, they correspond to the positions of the slots 210.

The plurality of holes 400 may include a plurality of side holes 410 and one top hole 420.

The side hole 410 refers to a hole positioned on the side of the nozzle 300, that is, in the direction facing the slot 210. The top hole 420 refers to a hole arranged on the upper surface of the nozzle 300.

The nozzle 300 may include a first nozzle 310 and a second nozzle 320.

The first nozzle 310 may be positioned lower than a wafer (w) positioned closer to the lower portion of the tube 100 among the plurality of wafers (w). That is, the first nozzle 310 refers to the nozzle 300 that is positioned below the wafer (w) placed at the lowest position.

Specifically, the wafer (w) placed in the first slot 210 among the slots 210 shown in FIG. 2A may be the wafer (w) placed at the very bottom, close to the bottom of the tube 100. Accordingly, the first nozzle 310 refers to a nozzle 300 located below the first slot 210, as shown in FIG. 2B.

The second nozzle 320 may be positioned above the first nozzle 310.

A plurality of side holes 410 may be arranged on the sides of the first nozzle 310 and the second nozzle 320.

A plurality of side holes 410 can be arranged in a row, spaced apart in one direction (X direction) along the length direction of the nozzle 300.

The plurality of side holes 410 may include a first side hole 412 arranged in the first nozzle 310 and a plurality of second side holes 414 arranged in the second nozzle 320.

In the thin film deposition device 10 according to the present disclosure, at least one of the plurality of holes 400 arranged in the nozzle 300 is characterized by having a different diameter.

The plurality of second side holes 414 may have a larger diameter toward the other side of the nozzle 300. That is, in the nozzle 300 placed in the tube 100, the size of the hole may increase from the first side hole 412 provided at the bottom of the tube 100 to the second side hole 414 provided at the top of the tube 100.

The top hole 420 is arranged at the other end of the nozzle 300 and can be arranged toward the upper surface of the tube 100. The gas (g) supplied through the top hole 420 may be sprayed upwards rather than toward the wafer (w).

According to embodiments, the first side hole 412, the second side hole 414, and the top hole 420 may each have different diameters.

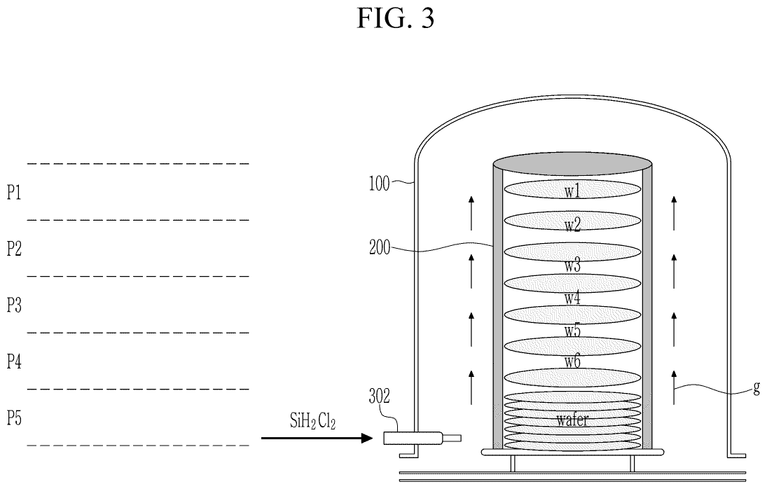

FIGS. 3 to 5 are drawings to explain problems that occur in the case of a horizontal nozzle.

FIG. 3 is a drawing illustrating the inside of a batch CVD equipment. The equipment illustrated in FIG. 3 is an example of a device having a horizontal nozzle 302, unlike the thin film deposition device 10 according to the present disclosure.

In the thin film deposition device 10 illustrated in FIG. 1, a nozzle 300 is arranged vertically along one direction (X) within a tube 100. The horizontal nozzle 302 arranged in FIG. 3 is different in that it is a horizontal nozzle 302 that is arranged only on the lower side of the tube 100 and is placed horizontally.

Gas (g) supplied through a horizontal nozzle 302 such as in FIG. 3 can diffuse upward inside the tube 100.

However, in the process of gas (g) supplied from the bottom diffusing upward, a problem may arise in which the gas distribution becomes uneven between the upper and lower regions within the tube 100. In particular, when the gas (g) supplied through the horizontal nozzle 302 is SiH₂Cl₂, there is a problem that the concentration distribution of SiH₂Cl₂ becomes uneven.

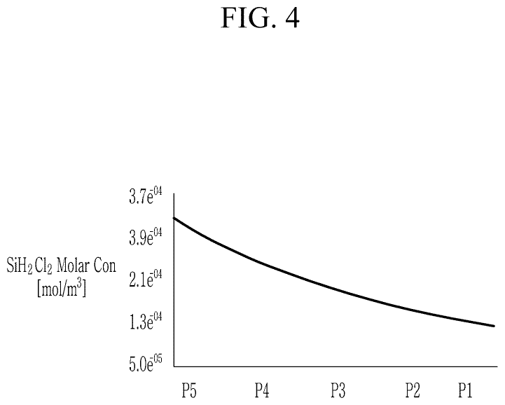

In FIG. 3, the area from the upper area to the lower area of the tube 100 is divided into a plurality of areas and indicated as P1, P2, P3, P4, and P5. FIG. 4 is a graph showing the gas distribution (SiH₂Cl₂ concentration distribution) within a tube 100 when gas (g) is supplied according to FIG. 3, and the distribution of gas (g) according to each area can be confirmed.

As shown in FIG. 4, the gas (g) concentration in P1, which is an upper region within the tube 100, and the gas (g) concentration in P5, which is a lower region within the tube 100, are different. Specifically, it can be confirmed that the concentration of gas (g) decreases as it goes from P5 to P1.

The molecular weight of SiH₂Cl₂ is 101 g/mol, which is larger than that of NH₃ (molecular weight: 17 g/mol). According to Graham's law of gas diffusion and Maxwell/Boltzmann velocity distribution laws, the larger the gas molecule, the smaller the diffusion rate.

In fact, the molecular weight of SiH₂Cl₂ is 5.93 times that of NH₃, and when comparing the speeds accordingly, the speed of NH₃ is 2.43 times faster than that of SiH₂Cl₂. In other words, the speed of SiH₂Cl₂ can be said to be 2.43 times slower than that of NH₃.

The slow diffusion rate of SiH₂Cl₂ affects the distribution of SiH₂Cl₂ within the tube 100. When the diffusion rate of the gas (g) itself within the tube 100, the influence of gravity, and the influence of the pressure within the tube 100 are all considered, SiH₂Cl₂ has a low distribution in the P1 region, as shown in FIG. 4.

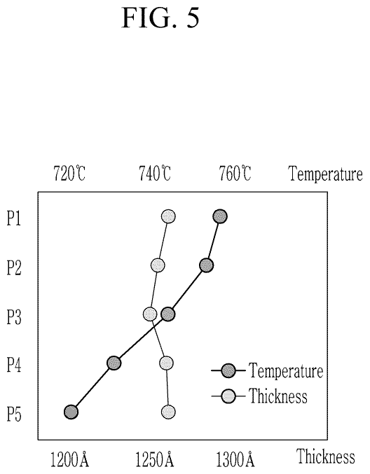

In this way, there is a method of controlling the temperature inside the tube 100 to compensate for the uneven gas distribution. FIG. 5 is a graph showing the results of controlling the temperature inside the tube 100 to uniformly control the uneven distribution of SiH₂Cl₂ inside the tube 100, as in FIG. 4.

As the temperature increases, the gas diffusion rate becomes faster. Therefore, as the temperature inside the tube 100 increases, the gas (g) diffusion rate inside the tube 100 becomes faster. Accordingly, in the P1 region, a method of raising the temperature higher can be used to uniformly distribute the gas within the tube 100.

As a result, by controlling the temperature as in FIG. 5 and uniformly distributing the gas, a thin film can be deposited so that the wafer (w) thickness is at a similar level.

That is, the graph shown in FIG. 5 means that the temperature inside the tube 100 is adjusted to compensate for the uneven gas distribution, and thus the gas distribution becomes uniform, so that the wafer (w) thickness becomes similar.

However, as in FIG. 5, when the temperature in the P1 to P5 regions is controlled to 720° C. to 760° C., there is a problem that a temperature deviation of about 25° C. to 40° C. occurs within the tube 100.

In this way, when a temperature deviation occurs within the tube 100, a problem occurs in which the propagation delay time (tPD; time Propagation Delay) dispersion increases.

Propagation delay time refers to the time it takes for a signal to propagate from input to output in a circuit. That is, it refers to the time it takes for a signal to travel from one point to another.

A wafer (w) is a substrate for semiconductor devices, and propagation delay time can be viewed as the time it takes for a signal to propagate within each transistor or other electronic device formed on the wafer (w) when the signal is processed.

Due to the difference in channel length (CL) on the wafer (w), dispersion occurs in the propagation delay time.

As the channel length (CL) becomes shorter, electrons move faster across the channel length (CL). Conversely, as the channel length (CL) increases, electrons move more slowly across the channel length (CL).

When the temperature of the area where the wafer (w) is placed is high, the channel length (CL) becomes short, and when the temperature is low, the channel length (CL) becomes relatively long.

As in FIG. 5, when the temperature of the P1 region is maintained at 760° C. and the temperature is gradually lowered so that the temperature of the P5 region is maintained at 720° C., a difference in channel length (CL) occurs between the wafers (w) placed from the P1 region to the P5 region. Due to the differences, there is bound to be a difference in propagation delay time. That is, dispersion occurs in the propagation delay time.

As described in FIGS. 3 to 5, if the nozzle supplying the SiH₂Cl₂ gas (g) inside the tube 100 is a horizontal nozzle 302, the diffusion distribution of the gas (g) inside the tube 100 becomes different. In order to make the gas distribution within the tube 100 uniform, a temperature difference must be provided. As a result, there is a problem that the propagation delay time dispersion in each area within the tube 100 increases due to temperature deviation.

In addition, in order to adjust the gas (g) concentration inside the tube 100, the supply amount of gas (g) is increased, but at this time, there is a problem of generating a solid powder byproduct inside the tube 100. For example, byproducts such as ammonium chloride form particles that cause defects in the wafer (w).

The thin film deposition device 10 according to the present disclosure is intended to improve the problems described in FIGS. 3 to 5.

The thin film deposition device 10 according to the present disclosure aims to minimize propagation delay time dispersion among plurality wafers (w) by uniformly distributing gas within the tube 100 during the process of supplying gas (g) within the tube 100 and thereby minimizing temperature deviation within the tube 100.

Uniform gas distribution within the tube 100 is the result of making the sizes of the plurality holes 400 different, as described in FIGS. 2A and 2B.

Specifically, by increasing the size of the hole 400 arranged in the upper region of the tube 100 where the gas distribution is low, a larger amount of gas (g) can be supplied to the upper region of the tube 100, thereby making the gas distribution within the tube 100 uniform.

In addition, the thin film deposition device 10 according to the present disclosure aims to ensure that gas (g) is supplied uniformly even on one wafer (w), thereby ensuring that deposition is as uniform as possible within one wafer (w).

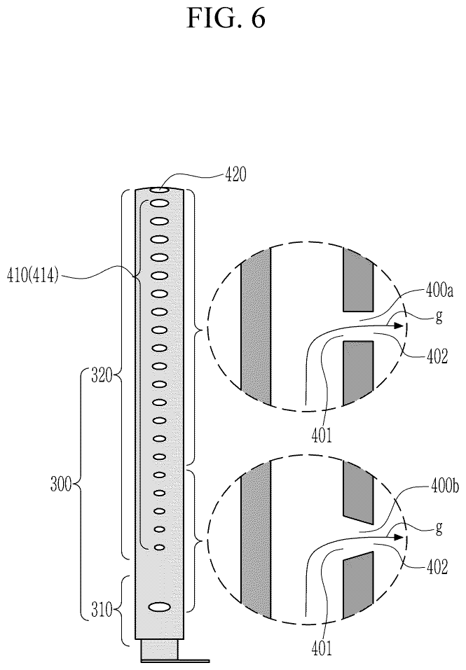

This means that the deposition reaction efficiency toward the center area of the wafer (w) is improved by changing the shape of the hole 400, as explained in FIG. 6 below.

FIG. 6 is a drawing illustrating a nozzle of a thin film deposition device according to embodiments.

Referring to FIG. 6, at least one of the plurality of holes 400 has a different shape The term “shape” refers to the appearance or shape of an object, and the plurality holes 400 may differ not only in size but also in appearance.

Specifically, the plurality of holes 400 penetrating the nozzle 300 may be straight holes 400a or convergence holes 400b.

A straight hole 400a means a hole in which the diameters of the first hole 401 formed inside the nozzle 300 and the second hole 402 formed outside the nozzle 300 are the same.

The convergence hole 400b refers to a hole shape in which the diameter of the first hole 401 is larger than the diameter of the second hole 402.

As illustrated in FIG. 6, the first side hole 412 arranged in the first nozzle 310 and the five second side holes 414 arranged in the lower part of the second nozzle 320 may have the shape of a convergence hole 400b.

Additionally, the remaining second side hole 414 of the second nozzle 320 and top hole 420 may have the shape of a straight hole 400a.

It is preferable that the convergence hole 400b is arranged at the lower part of the nozzle 300 including the lower part of the first nozzle 310 and the second nozzle 320, and the straight hole 400a is arranged at the upper part of the second nozzle 320. However, the number of straight holes 400a and convergence holes 400b arranged is not limited to the positions and number shown in FIG. 6.

The flow rates of gas (g) passing through a straight hole 400a having the same diameter as the first hole 401 and the second hole 402 and gas (g) passing through a convergence hole 400b are compared as follows.

In the case of the convergence hole 400b, when the gas (g) moves through the first hole 401 to the second hole 402, the flow rate of the gas (g) increases when it passes through the second hole 402 which has a smaller diameter than the first hole 401. As the same amount of gas (g) moves, the flow rate of the gas (g) increases because the path of movement becomes narrower.

In general, gas (g) injected from the hole 400 moves onto a wafer (w) loaded on a boat 200. In fact, most of the injected gas (g) moves only to the edge region of the wafer (w) positioned close to the nozzle 300.

Accordingly, the amount of gas (g) moving to the center of the wafer (w) is extremely small.

As described above, the gas (g) supplied from the nozzle 300 generally does not travel far and is mostly deposited at the edge of the wafer (w) located nearby. Accordingly, there is a problem that deposition hardly occurs at the center of the wafer (w). As a result, the deposition reaction efficiency is low in the center region of the wafer (w).

In the thin film deposition device 10 according to the present disclosure, the hole 400 in the form of a convergent hole 400b is arranged in the lower region of the nozzle 300 to increase the flow rate of the gas (g) sprayed in the lower region of the nozzle 300, so that the sprayed gas (g) can move to the center of the wafer (w). That is, the purpose is to improve the deposition reaction efficiency toward the center area of the wafer (w).

A convergence hole 400b is not arranged in the upper area of the nozzle 300. Accordingly, there is no effect of increasing the flow rate of gas (g). However, by arranging a hole 400 in the form of a straight hole 400a in the upper region of the nozzle 300 and increasing the size of the hole 400, there is an effect of increasing the amount of gas (g) supplied compared to the lower region of the nozzle 300.

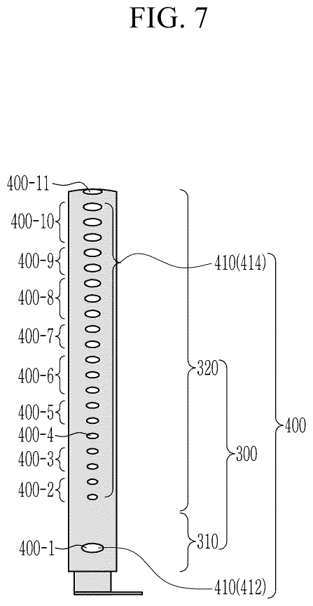

FIG. 7 is a drawing illustrating a nozzle of a thin film deposition device according to embodiments.

As illustrated in FIG. 7, the plurality of holes 400 may have various sizes.

The diameter of the 22 holes 400 arranged in the nozzle 300 may be 1.3 mm or more and 3.0 mm or less.

It may include one first side hole 412, twenty second side holes 414, and one top hole 420.

The diameter of the first side hole 412 (400-1) may be 2.5 mm or more and 3.0 mm or less.

The diameter of the plurality of second side holes 414 (400-2, 400-3, 400-4, 400-5, 400-6, 400-7, 400-8, 100-9, 400-10) may be 1.3 mm or more and 2.1 mm or less.

The diameter of the top hole 420 (400-11) may be 2.3 mm or more and 2.5 mm or less.

Preferably, the diameter of the first side hole 400-1 can be 3.0 mm.

In addition, the diameter of two second side holes 400-2 may be 1.3 mm, the diameter of two second side holes 400-3 may be 1.4 mm, the diameter of one second side hole 400-4 may be 1.5 mm, the diameter of two second side holes 400-5 may be 1.6 mm, the diameter of three second side holes 400-6 may be 1.7 mm, the diameter of two second side holes 400-7 may be 1.8 mm, the diameter of three second side holes 400-8 may be 1.9 mm, the diameter of two second side holes 400-9 may be 2.0 mm, and the diameter of three second side holes 400-10 may be 2.1 mm.

Additionally, the diameter of the top hole 420 (400-11) can be 2.4 mm.

When 22 holes 400 have the respective diameters described above and have the shape of a convergence hole 400b and a straight hole 400a as in FIG. 6, gas (g) can be supplied so that the distribution of gas (g) within the tube 100 becomes uniform. At the same time, the deposition reaction efficiency in the center area of the wafer (w) can be optimized.

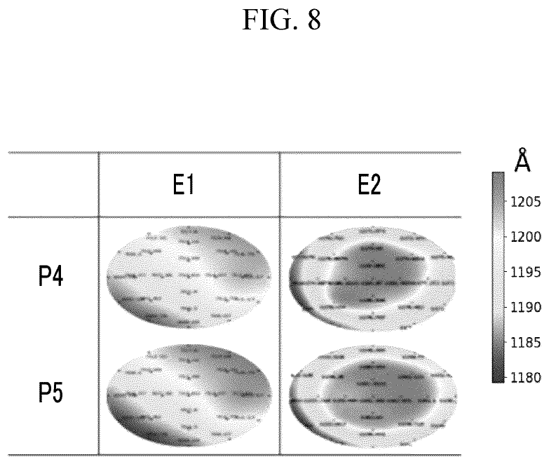

FIG. 8 is a drawing to explain the difference in deposition thickness on the wafer.

E1 shows the deposition thickness of the wafer (w) when the deposition process is performed in a batch CVD equipment including a horizontal nozzle 302 as shown in FIG. 3.

E2 represents the deposition thickness of the wafer (w) when a deposition process is performed in the thin film deposition device 10 according to the present disclosure illustrated in FIG. 1.

P4 and P5 represent a portion of the lower region among the regions extending from the upper region to the lower region of the tube 100 (see FIG. 3).

In the case of E1, it can be seen that the deposition reaction progresses significantly only at one edge of the wafer (w), and that the deposition reaction hardly progresses at the other edge. It can be confirmed that the deposition reaction efficiency is not good in the center area of the wafer (w).

When comparing E1 and E2, it can be confirmed that the deposition reaction efficiency in the center area of the wafer (w) is improved in the case (E2) where the gas (g) is supplied using the nozzle 300 according to the present disclosure compared to the case (E1) where the gas (g) is supplied using the horizontal nozzle 302 in FIG. 3.

That is, in the thin film deposition device 10 according to the present disclosure, by arranging a hole 400 in the form of a convergent hole 400b in the lower region of the nozzle 300, the injected gas (g) moves to the center of the wafer (w), thereby causing a further deposition reaction.

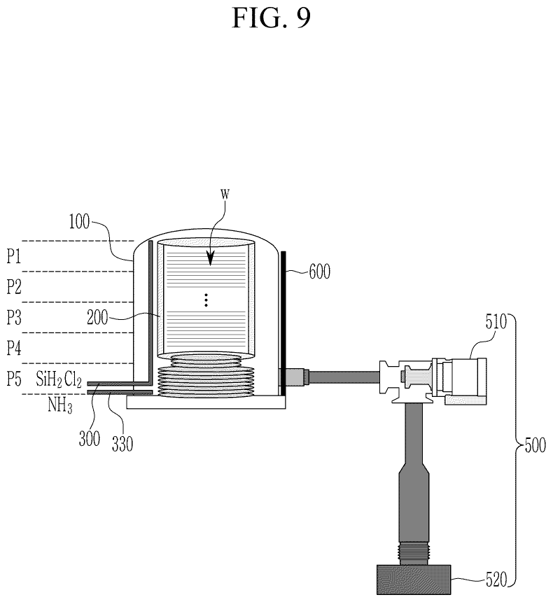

FIG. 9 is a drawing illustrating a thin film deposition device according to embodiments.

As illustrated in FIG. 9, a thin film deposition device 10 according to the present disclosure may include a tube 100, a boat 200, a nozzle 300, and a pressure controller 500.

The boat 200 is placed inside the tube 100 and can load a plurality of wafers (w) spaced apart in parallel.

The nozzle 300 is positioned within the tube 100 and may include a plurality of holes 400 that supply gas (g) toward the wafer (w). As described in FIGS. 1, 2, 6, and 7, at least one of the plurality of holes 400 arranged in the nozzle 300 illustrated in FIG. 9 may have a different diameter.

The nozzle 300 supplies gas (g) toward the wafer (w) loaded on the boat 100. As long as the gas (g) sprayed from the nozzle 300 can move into the boat 200 and be deposited on the wafer (w), the position of the nozzle 300 is not limited.

The pressure controller 500 functions to control the pressure inside the tube 100 to a low pressure.

The pressure controller 500 may include a valve 510 for controlling pressure and a suction pump 520 for controlling vacuum within the tube 100.

The pressure controller 500 according to the present disclosure can control the pressure inside the tube 100 to be 10 Pa or more and 20 Pa or less.

The thin film deposition device 10 may further include an NH₃ nozzle 330 that supplies NH₃ into the tube 100. In addition, the thin film deposition device 10 may further include a heater 600 that is placed outside the tube 100 and heats the inside of the tube 100. By transferring heat from the heater 600 to the inside of the tube 100, the temperature of the gas (g) inside the tube 100 can be increased.

In FIG. 9, embodiments is illustrated in which the heater 600 is placed outside the tube 100. The heater 600 is for heating the gas (g) moving inside the boat 200. As long as the gas (g) can be heated, the position of the heater 600 is not limited. Depending on the embodiment, the heater 600 may be placed inside the tube 100 and outside the boat 200.

A thin film deposition device 10 according to embodiments may include a tube 100, a boat 200 arranged in the tube 100 and configured to load a plurality of wafers (w) spaced apart in parallel, a nozzle 300 fixed at one end to a lower side of the tube 100 and disposed within the tube 100 such that the other end is proximate to an upper side of the tube 100, and a pressure controller 500 that adjusts the pressure inside the tube 100 to be low pressure.

The nozzle 300 may include a plurality of holes 400 that supply gas (g) toward the wafer (w). Among the plurality holes 400, the hole 400 arranged in the second nozzle 320 is characterized in that its diameter increases as it approaches the other side of the nozzle 300.

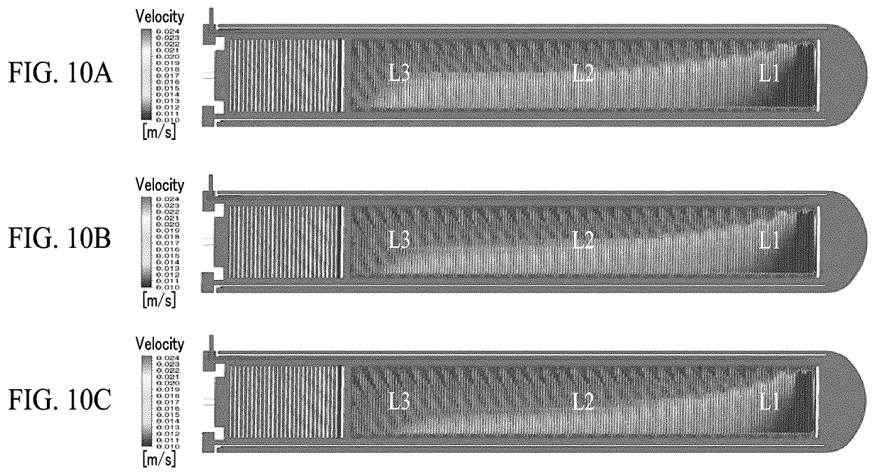

FIGS. 10A, 10B and 10C are drawings illustrating changes in the flow rate of gas injected inside a tube. FIGS. 10A, 10B and 10C show an analysis of the change in the flow rate of gas (g) when a thin film deposition device 10 including a nozzle 300 equipped with a hole 400 such as that in FIGS. 6 and 7 is used.

The injection speed of gas (g) supplied from the hole 400 is proportional to the difference between the pressure inside the nozzle 300 and the pressure inside the tube 100. Accordingly, when the pressure inside the tube 100 is reduced, the injection speed of the gas (g) increases.

The injection speed of gas (g) can be referred to as the flow rate of gas (g), and the faster the flow rate of gas (g), the greater the distance that gas (g) can move. That is, as the pressure inside the tube 100 decreases, the distance through which the gas (g) moves increases.

FIG. 10A shows the change in the flow rate of gas (g) when the deposition process is performed while maintaining the pressure inside the tube 100 at 25 Pa. FIG. 10B shows the change in the flow rate of gas (g) when the deposition process is performed while maintaining the pressure inside the tube 100 at 20 Pa. FIG. 10C shows the change in the flow rate of gas (g) when the deposition process was performed while maintaining the pressure inside the tube 100 at 15 Pa.

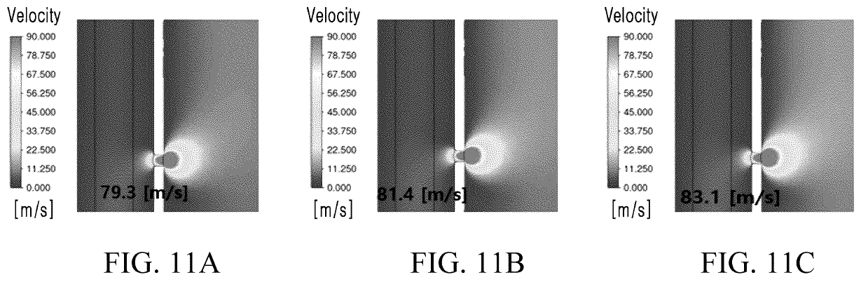

FIGS. 11A, 11B, 11C, 12A, 12B, 12C, 13A, 13B and 13C are drawings illustrating the injection speed of gas injected from the nozzle of FIGS. 10A, 10B and 10C.

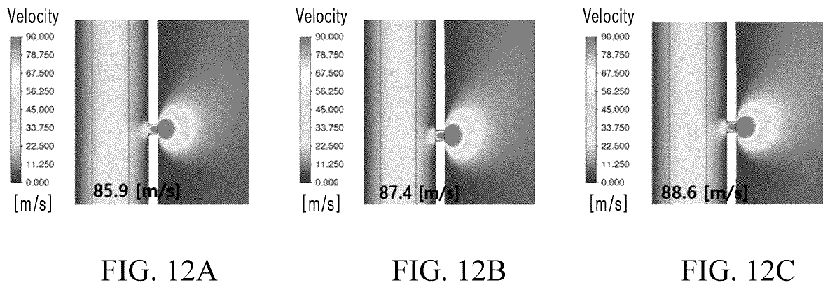

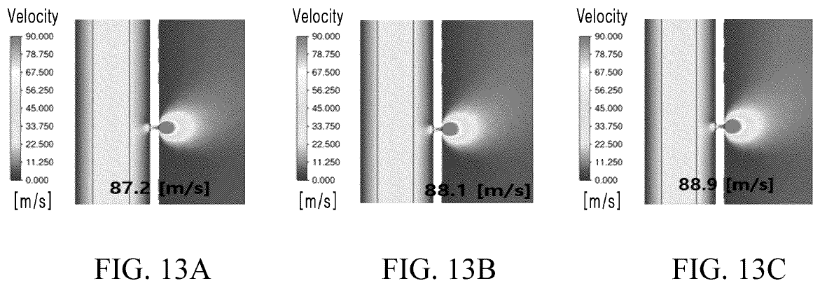

FIGS. 11A, 11B, and 11C are enlarged drawings of the L1 region shown in FIGS. 10A, 10B, and 10C, respectively. FIGS. 12A, 12B, and 12C are enlarged drawings of the L2 region shown in FIGS. 10A, 10B, and 10C, respectively. FIGS. 13A, 13B, and 13C are enlarged drawings of the L3 region shown in FIGS. 10A, 10B, and 10C, respectively.

FIG. 11A is a drawing showing the flow rate of gas (g) sprayed from a hole 400 located on the upper side (L1) of the tube 100 when the deposition process is performed by maintaining the pressure inside the tube 100 at 25 Pa (L1 of FIG. 10A). FIG. 11B is a drawing showing the flow rate of gas (g) sprayed from a hole 400 located on the upper side (L1) of the tube 100 when the deposition process is performed by maintaining the pressure inside the tube 100 at 20 Pa (L1 of FIG. 10B). FIG. 11C is a drawing showing the flow rate of gas (g) sprayed from a hole 400 located on the upper side (L1) of the tube 100 when the deposition process is performed by maintaining the pressure inside the tube 100 at 15 Pa (L1 of FIG. 10C).

FIG. 12A is a drawing showing the flow rate of gas (g) sprayed from a hole 400 located in the middle (L2) of a tube 100 when the deposition process is performed by maintaining the pressure inside the tube 100 at 25 Pa (L2 of FIG. 10A). FIG. 12B is a drawing showing the flow rate of gas (g) sprayed from a hole 400 located in the middle (L2) of a tube 100 when the deposition process is performed by maintaining the pressure inside the tube 100 at 20 Pa (L2 of FIG. 10B). FIG. 12C is a drawing showing the flow rate of gas (g) sprayed from a hole 400 located in the middle (L2) of a tube 100 when the deposition process is performed by maintaining the pressure inside the tube 100 at 15 Pa (L2 of FIG. 10C).

FIG. 13A is a drawing showing the flow rate of gas (g) sprayed from a hole 400 located at the lower side (L3) of the tube 100 when the deposition process is performed by maintaining the pressure inside the tube 100 at 25 Pa (L3 of FIG. 10A). FIG. 13B is a drawing showing the flow rate of gas (g) sprayed from a hole 400 located at the lower side (L3) of the tube 100 when the deposition process is performed by maintaining the pressure inside the tube 100 at 20 Pa (L3 in FIG. 10B). FIG. 13C is a drawing showing the flow rate of gas (g) sprayed from a hole 400 located at the lower side (L3) of the tube 100 when the deposition process is performed by maintaining the pressure inside the tube 100 at 15 Pa (L3 in FIG. 10C).

Referring to FIGS. 11 to 13, the flow rate of gas (g) in FIG. 10A (when the deposition process is performed by maintaining the pressure inside the tube 100 at 25 Pa) falls within the range of 79.3 to 87.2 m/s.

In FIG. 10B (when the deposition process is performed by maintaining the pressure inside the tube 100 at 20 Pa), the flow rate of gas (g) is in the range of 81.4 to 88.1 m/s. The flow rate of gas (g) in FIG. 10C (when the deposition process is performed by maintaining the pressure inside the tube 100 at 15 Pa) is in the range of 83.1 to 88.9 m/s.

Through this, it can be confirmed that as the pressure inside the tube 100 decreases, the flow rate of gas (g) increases.

An increase in the flow rate of gas (g) means that the distance moved by the gas (g) increases, allowing the injected gas (g) to move to the center of the wafer (w). That is, as the pressure inside the tube 100 decreases, the deposition reaction efficiency in the center area of the wafer (w) improves.

The pressure controller 500 can control the pressure inside the tube 100 to 10 to 20 Pa. However, in reality, when considering the equipment variables (such as pipe blockage) that occur due to pressure control, it is preferable that the pressure controller 500 control the pressure inside the tube 100 to 20 Pa.

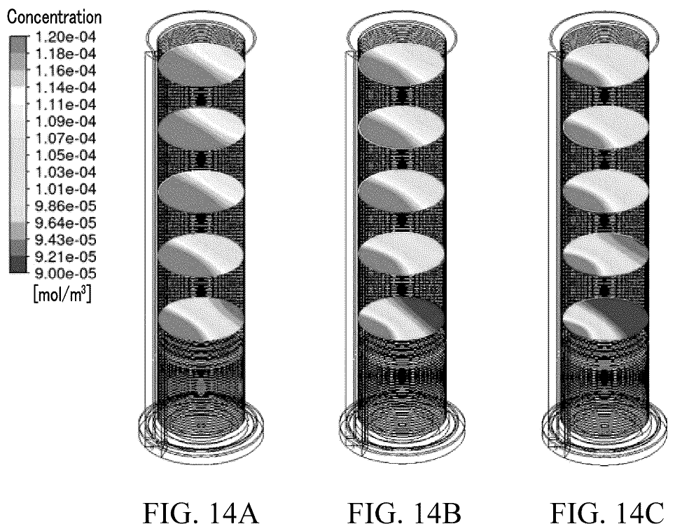

FIGS. 14A, 14B and 14C are drawings illustrating the concentration distribution of gas deposited on a wafer. FIGS. 14A, 14B and 14C show an analysis of the concentration distribution of gas (g) deposited on a wafer (w) when using a nozzle 300 such as those in FIGS. 6 and 7.

FIG. 14A shows the concentration distribution of gas (g) deposited on a wafer (w) when a deposition process is performed by maintaining the pressure inside a tube 100 at 25 Pa using a thin film deposition device 10 according to the present disclosure. FIG. 14B shows the concentration distribution of gas (g) deposited on a wafer (w) when the deposition process is performed while maintaining the pressure inside the tube 100 at 20 Pa. FIG. 14C shows the concentration distribution of gas (g) deposited on a wafer (w) when the deposition process is performed while maintaining the pressure inside the tube 100 at 15 Pa.

In the case of FIG. 14A, when examining the concentration distribution of gas (g) deposited on each wafer (w), it can be confirmed that the concentration of gas (g) is high in a specific direction.

Looking at FIG. 14B, it can be confirmed that the concentration of gas (g) deposited at an edge portion in a specific direction is lower than in FIG. 14A. In addition, it can be confirmed that the concentration of gas (g) deposited at the edge portion in FIG. 14C is lower than in FIG. 14B.

That is, compared to FIG. 14A, in FIG. 14C, it can be confirmed that the area to which the concentration of gas (g) is biased toward a specific direction of the wafer (w) is narrowed.

In fact, since the gas (g) supplied from the nozzle 300 is structured to be supplied from one direction, it is deposited from one direction of the wafer (w), causing eccentricity. To prevent this, the deposition process is generally performed while rotating the boat 200. However, even though the boat 200 rotates, the wafer (w) placed in the lower area of the boat 200 has a severe eccentricity phenomenon in the edge area (see FIG. 14A).

To minimize this eccentricity, the pressure conditions inside the tube 100 can be changed. FIGS. 14A to 14C show changes in the concentration distribution of gas (g) deposited on a wafer (w) in a deposition reaction while changing the pressure conditions inside the tube 100.

In a deposition reaction, when the eccentricity at the edge of the wafer (w) is severe (FIGS. 14A, 25 Pa), when the pressure inside the tube 100 is lowered (FIGS. 14B, 20 Pa)/(FIGS. 14C, 15 Pa), the pressure difference between the pressure inside the tube 100 and the pressure of the nozzle 300 increases. Accordingly, the injection velocity of gas (g) increases.

As a result, there is an effect of increasing the gas (g) reaching the center area of the wafer (w). That is, there is an effect of increasing the reaction distance of gas (g). Looking at the drawing, it can be confirmed that the area that was eccentric to one edge of the wafer (the area with high gas (g) concentration) has narrowed.

This means that the gas (g), which could only reach the edge of the wafer (w), can now reach the center of the wafer (w) as the pressure inside the tube 100 is reduced, thereby minimizing the eccentricity that occurred in the edge region.

Accordingly, in the thin film deposition device 10 according to the present disclosure, it is preferable that the pressure controller 500 control the pressure inside the tube 100 to 15 to 20 Pa.

When examining the wafer (w) illustrated in FIGS. 14B and 14C and the wafer (w) illustrated in FIG. 14A, the gas (g) concentration appears to be higher overall on the wafer (w) illustrated in FIG. 14A.

That is, in FIG. 14A, it can be seen that the conditions in FIG. 14A are vulnerable in terms of eccentricity through the fact that the concentration of gas (g) on the surface of the wafer (w) is high overall.

As a result, it can be seen that as one goes from FIG. 14A to C (as the pressure inside the tube 100 decreases), the concentration of gas (g) on the surface of the wafer (w) generally decreases, which means that the eccentricity on the wafer (w) can be improved.

As described above, the thin film deposition device 10 according to the present disclosure aims to reduce the deposition thickness deviation occurring within each wafer (w) by controlling the flow rate of gas (g) supplied onto a wafer (w) placed within a tube 100. In addition, by supplying gas (g) so that the gas distribution inside the tube 100 becomes uniform, there is an effect of reducing the thickness deviation between plurality wafers (w).

In addition, it is significant in that it reduces the temperature deviation within the tube 100 in the process of uniformly supplying gas (g), thereby minimizing the propagation delay time dispersion.

Although the embodiments of the present disclosure have been described in detail above, the scope of the present disclosure is not limited thereto, and various modifications and improvements made by those skilled in the art using the basic concepts of the present disclosure defined in the following claims also fall within the scope of the present disclosure.

In addition, the embodiments of the present disclosure are not independent of each other and may be implemented in combination with each other unless there is a specific contradiction. Accordingly, embodiments in which the embodiments of the present disclosure are combined should also be considered to be included in the present disclosure.

What is claimed is:

1. A thin film deposition device, comprising:
a tube;
a boat disposed within the tube and configured to load a plurality of wafers in parallel at spaced intervals; and
a nozzle disposed within the tube along one direction and including a plurality of holes configured to supply a gas toward the wafers,
wherein at least one of the plurality of holes has a diameter different from a diameter of at least one of the other holes.

2. The thin film deposition device of claim 1, wherein the nozzle is fixed at one end to a lower side of the tube, and is disposed within the tube such that another end of the nozzle is positioned proximate to an upper side of the tube.

3. The thin film deposition device of claim 2, wherein the plurality of holes comprises:
a plurality of side holes arranged in a line and spaced apart along a longitudinal direction of the nozzle; and
a top hole formed at the other end of the nozzle and directed toward an upper surface of the tube.

4. The thin film deposition device of claim 3, wherein the nozzle comprises:
a first nozzle disposed below a wafer that is positioned closest to a lower portion of the tube among the plurality of wafers; and
a second nozzle disposed above the first nozzle,
wherein the plurality of side holes is formed on side surfaces of both the first and second nozzle.

5. The thin film deposition device of claim 4, wherein the plurality of side holes comprises:
a first side hole disposed on the first nozzle; and
a plurality of second side holes disposed on the second nozzle.

6. The thin film deposition device of claim 5,
wherein the diameters of the plurality of second side holes increase toward the other end of the nozzle.

7. The thin film deposition device of claim 5,
wherein the first side hole, the second side holes, and the top hole each has different diameters.

8. The thin film deposition device of claim 5,
wherein the diameter of the top hole is between 2.3 mm and 2.5 mm.

9. The thin film deposition device of claim 5,
wherein the diameter of the first side hole is between 2.5 mm and 3.0 mm.

10. The thin film deposition device of claim 5,
wherein the diameters of the plurality of second side holes range from 1.3 mm to 2.1 mm.

11. The thin film deposition device of claim 1,
wherein at least one of the plurality of holes has a different shape.

12. The thin film deposition device of claim 1, wherein the plurality of holes comprises:
a straight hole having a same diameter as that of a first hole formed inside the nozzle and that of a second hole formed outside the nozzle; and
a convergence hole, the diameter of the first hole being larger than the diameter of the second hole.

13. The thin film deposition device of claim 1,
wherein the nozzle is configured to be disposed in a plurality.

14. The thin film deposition device of claim 1,
further comprising an NH₃ nozzle configured to supply NH₃ into the tube.

15. The thin film deposition device of claim 1, wherein:
wherein the diameters of the plurality of holes range from 1.3 mm to 3.0 mm.

16. A thin film deposition device, comprising:
tube;
a boat disposed within the tube and configured to load a plurality of wafers in parallel;
a nozzle disposed within the tube and including a plurality of holes configured to supply a gas toward the wafers; and
a pressure controller configured to adjust the pressure inside the tube to be low pressure,
wherein at least one of the plurality of holes has a different diameter than a diameter of at least another of the plurality of holes.

17. The thin film deposition device of claim 16, wherein the pressure controller comprises:
a valve configured to control the pressure; and
a suction pump configured to control the vacuum within the tube.

18. The thin film deposition device of claim 16,
wherein the pressure controller is configured to adjust the pressure within the tube to be between 10 Pa and 20 Pa.

19. The thin film deposition device of claim 16,
further comprising a heater disposed outside the tube and configured to heat the inside of the tube.

20. A thin film deposition device, comprising:
tube;
a boat disposed within the tube and configured to load a plurality of wafers in parallel;
a nozzle fixed at one end to a lower side of the tube and disposed within the tube such that the other end is proximate to an upper side of the tube, the nozzle including a plurality of holes configured to supply a gas toward the wafers; and
a pressure controller configured to adjust the pressure inside the tube to be low pressure,
wherein some of the plurality of holes have diameters that increase toward the other end of the nozzle.
